(19) United States
(12) Patent Application Publication
(10) Pub. No.: US 2026/0206606 A1
(43) Pub. Date: Jul. 16, 2026

(54) SEMICONDUCTOR PACKAGE WITH HEAT TRANSFER LAYER

(71) Applicant: SAMSUNG ELECTRONICS CO., LTD., Suwon-si (KR)

(72) Inventors: Wook Moon, Suwon-si (KR); Byunghan Ko, Suwon-si (KR); Hwanjoo Park, Suwon-si (KR); Sun-ki Yun, Suwon-si (KR); Jeonggi Yoon, Suwon-si (KR)

(73) Assignee: SAMSUNG ELECTRONICS CO., LTD., Suwon-si (KR)

(21) Appl. No.: 19/291,131

(22) Filed: Aug. 5, 2025

(30) Foreign Application Priority Data
Jan. 14, 2025 (KR) 10-2025-0005577

(51) Int. Cl. H10W 46/00; H10B 80/00; H10W 40/10; H10W 90/00

(52) U.S. Cl. CPC H10W 46/00; H10B 80/00; H10W 40/10; H10W 90/00; H10W 46/301

(57) ABSTRACT

Provided is a semiconductor package including: a substrate including an upper surface and a lower surface on opposite sides of the substrate; a memory package on the lower surface of the substrate; a guide mark on the upper surface of the substrate, wherein the guide mark is recessed from the upper surface of the substrate toward an inside of the substrate; a heat transfer layer on the upper surface of the substrate, wherein the heat transfer layer vertically overlaps with the memory package; and a device horizontally spaced apart from the heat transfer layer on the upper surface of the substrate, wherein the guide mark is between a region in which the heat transfer layer is provided and a region in which the device is provided.

### CROSS-REFERENCE TO RELATED APPLICATION

This U.S. non-provisional patent application is based on and claims priority to Korean Patent Application No. 10-2025-0005577, filed in the Korean Intellectual Property Office on January 14, 2025, the entire contents of which are hereby incorporated by reference.

### BACKGROUND

The present disclosure relates to a semiconductor package.

With development of the electronics industry, demand for high-functionality, high-speed, high-capacity and miniaturization of an electronic component is increasing. In response to this trend, recent packaging technology is moving in a direction in which a plurality of semiconductor chips are mounted in one package.

A semiconductor package is an integrated circuit chip implemented in a form suitable for use in an electronic product. In general, the semiconductor package is manufactured by mounting the semiconductor chip on a printed circuit board (PCB), and electrically connecting the same by using a bonding wire or a bump. As the electronics industry has developed, there is a need for the continuing development of semiconductor packages in connection with characteristics such as miniaturization, weight reduction, and reduction of manufacturing cost. In order to realize the miniaturization and the weight reduction of electronic components, not only is a technology that reduces an individual size of the mounted component required, but a semiconductor package technology that integrates many individual devices into a single package is also required.

However, with increased speed and capacity of semiconductor packages comes increasing power consumption of the semiconductor package. Accordingly, thermal characteristics of the semiconductor package become increasingly important.

### SUMMARY

Provided is a semiconductor package with improved thermal characteristics.

Further provided is a semiconductor package with improved electrical stability.

The present disclosure is not limited to the aspects and features mentioned above, and other aspects and features that are not mentioned may be clearly understood by those skilled in the art from the description below.

According to an aspect of the disclosure, a semiconductor package includes: a substrate including an upper surface and a lower surface on opposite sides of the substrate; a memory package on the lower surface of the substrate; a guide mark on the upper surface of the substrate, wherein the guide mark is recessed from the upper surface of the substrate toward an inside of the substrate; a heat transfer layer on the upper surface of the substrate, wherein the heat transfer layer vertically overlaps with the memory package; and a device horizontally spaced apart from the heat transfer layer on the upper surface of the substrate, wherein the guide mark is between a region in which the heat transfer layer is provided and a region in which the device is provided.

According to an aspect of the disclosure, a semiconductor package includes: a substrate; a memory package on a lower surface of the substrate; and a heat transfer layer on an upper surface of the substrate, wherein the heat transfer layer vertically overlaps with the memory package, wherein the substrate includes: a core layer; an upper substrate wire layer on an upper surface of the core layer; and an upper insulating layer on an upper surface of the upper substrate wire layer, wherein the upper substrate wire layer includes at least one first hole recessed from the upper surface of the upper substrate wire layer toward an inside of the upper substrate wire layer, and wherein the at least one first hole extends along at least a portion of a border of the heat transfer layer.

According to an aspect of the disclosure, a semiconductor package includes: a substrate including a guide mark protruding from an upper surface of the substrate; a memory package on a lower surface of the substrate; and a heat transfer layer on the upper surface of the substrate, wherein the heat transfer layer vertically overlaps with the memory package, and wherein the guide mark at least partially surrounds a border of the heat transfer layer.

According to an embodiment of the disclosure, a method of manufacturing a semiconductor package includes forming a guide mark on an upper surface of a substrate, mounting a memory package on a lower surface of the substrate, and mounting a heat transfer layer on the upper surface of the substrate so as to vertically overlap the memory package, wherein on a plan view, the guide mark is formed so as to at least partially surround a border of the heat transfer layer.

In an embodiment, the method for manufacturing a semiconductor package may further include mounting devices horizontally spaced apart from the heat transfer layer on the upper surface of the substrate, wherein the guide mark may be formed between a region in which the heat transfer layer is provided and a region in which the devices are provided.

In an embodiment, the substrate may include a core layer, an upper substrate wire layer on an upper surface of the core layer, and an upper insulating layer covering an upper surface of the upper substrate wire layer, and the forming of the guide mark may include forming the upper substrate wire layer on the core layer, forming the upper insulating layer on the upper substrate wire layer, and forming the guide mark by patterning the upper insulating layer.

In an embodiment, the substrate may include a core layer, an upper substrate wire layer on an upper surface of the core layer, and an upper insulating layer covering an upper surface of the upper substrate wire layer, the forming of the guide mark may include forming the upper substrate wire layer on the core layer, forming the upper insulating layer on the upper substrate wire layer, and forming the guide mark on the upper insulating layer in a silk screen process, and the guide mark may protrude onto the upper surface of the substrate.

In an embodiment, the substrate may include a core layer, an upper substrate wire layer on an upper surface of the core layer, and an upper insulating layer covering an upper surface of the upper substrate wire layer, the forming of the guide mark may include forming the upper substrate wire layer on the core layer, forming a first hole by patterning the upper substrate wire layer, and forming the upper insulating layer on the upper substrate wire layer, the upper insulating layer may include a second hole vertically aligned with the first hole, and penetrating the upper insulating layer, and the first hole and the second hole may constitute a guide mark simultaneously penetrating the upper insulating layer and the upper substrate wire layer.

In an embodiment, the substrate may include a core layer, an upper substrate wire layer on an upper surface of the core layer, and an upper insulating layer covering an upper surface of the upper substrate wire layer, the forming of the guide mark may include forming the upper substrate wire layer on the core layer, forming a first hole by patterning the upper substrate wire layer, and forming the upper insulating layer on the upper substrate wire layer, the upper insulating layer may cover inner side surfaces and a bottom surface of the first hole, the upper insulating layer may have a step in a region in which the first hole is formed, and the step may constitute the guide mark.

According to an embodiment of the disclosure, a method of manufacturing a semiconductor package includes: forming an upper substrate wire layer on an upper surface of a core layer, the upper substrate wire layer including an upper substrate insulating pattern and an upper substrate wire pattern; forming an upper insulating layer on the upper substrate wire layer; patterning the upper insulating layer to form a guide mark; mounting a heat transfer layer on the upper insulating layer, wherein the heat transfer layer is mounting within a region defined by the guide mark; mounting a device on the upper insulating layer, wherein the device is horizontally spaced apart from the heat transfer layer and the guide mark is at least partially between the device and the heat transfer layer.

### BRIEF DESCRIPTION OF DRAWINGS

The above and other aspects and features of certain embodiments of the present disclosure will be more apparent from the following description taken in conjunction with the accompanying drawings, in which:

FIGS. 1 and 2 are perspective views for describing a semiconductor package according to one or more embodiments of the present disclosure;

FIG. 3A is a cross-sectional view, for describing a semiconductor package according to one or more embodiments of the present disclosure, taken along line A-A’ of FIG. 2;

FIG. 3B is an enlarged diagram illustrating region P1 of FIG. 3A;

FIG. 4A is a plan view for describing a semiconductor package according to one or more embodiments of the present disclosure;

FIG. 4B is a cross-sectional view, for describing a semiconductor package according to one or more embodiments of the present disclosure, taken along line B-B’ of FIG. 4A;

FIGS. 5A, 5B, 5C, and 5D are plan views for describing a semiconductor package according to one or more embodiments of the present disclosure;

FIG. 6 is a cross-sectional view for describing a semiconductor package according to one or more embodiments of the present disclosure;

FIGS. 7A, 7B, and 7C are cross-sectional views for describing a semiconductor package according to one or more embodiments of the present disclosure; and

FIGS. 8, 9, 10A, 10B, 11A, 11B, and 11C are cross-sectional views for describing a method for manufacturing a substrate of a semiconductor package according to one or more embodiments of the present disclosure.

### DETAILED DESCRIPTION

Hereinafter, a semiconductor package according to the present disclosure will be described with reference to the drawings.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only a configuration where the member is in contact with the other member, but also a configuration where there is another member between the two members.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, the disclosure is not be limited by these terms, and these terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

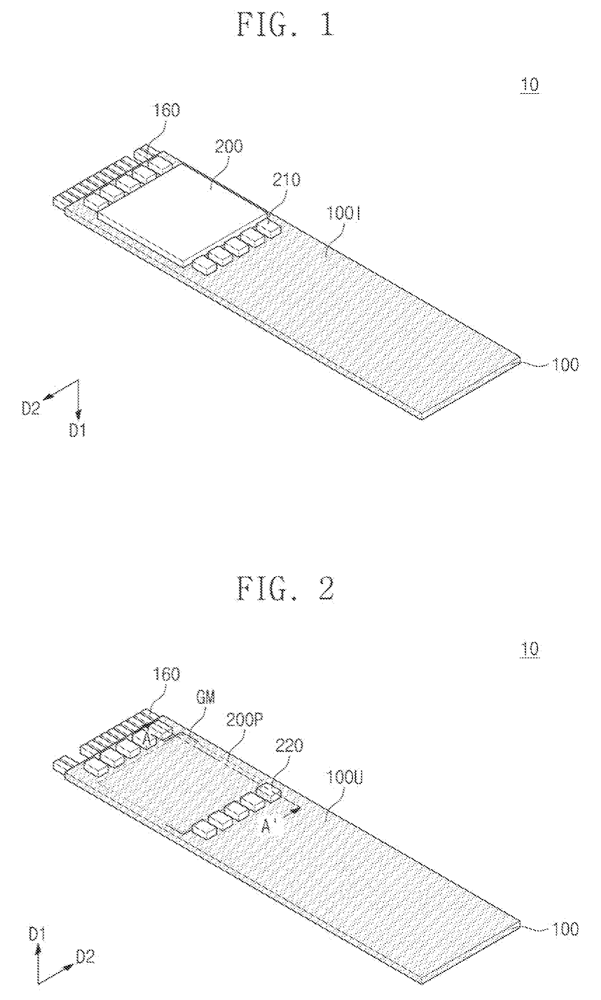

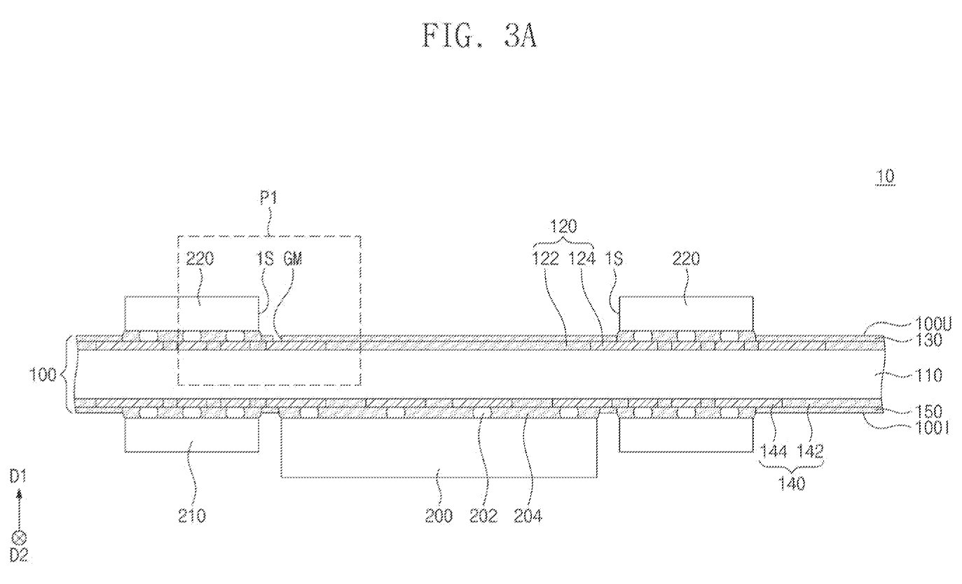

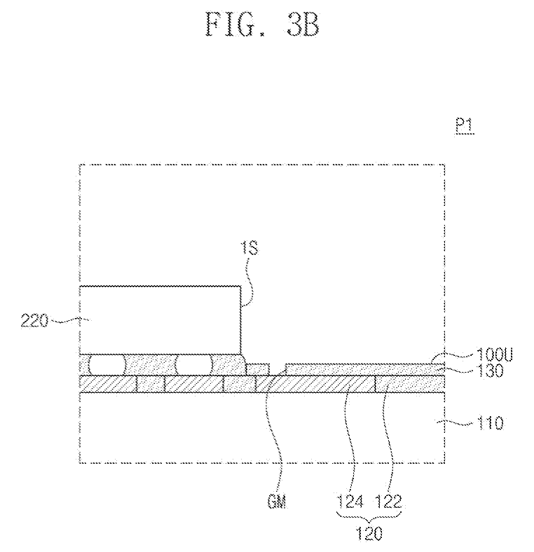

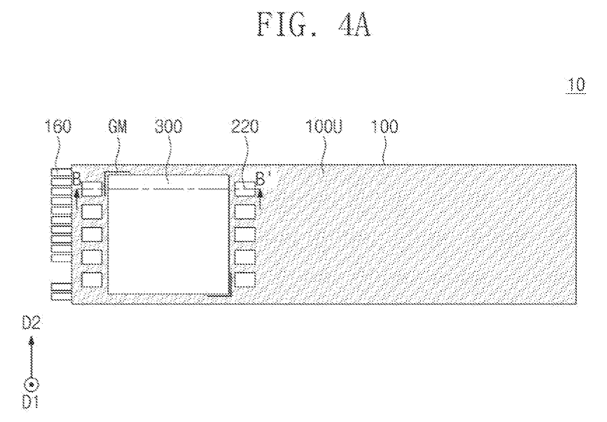

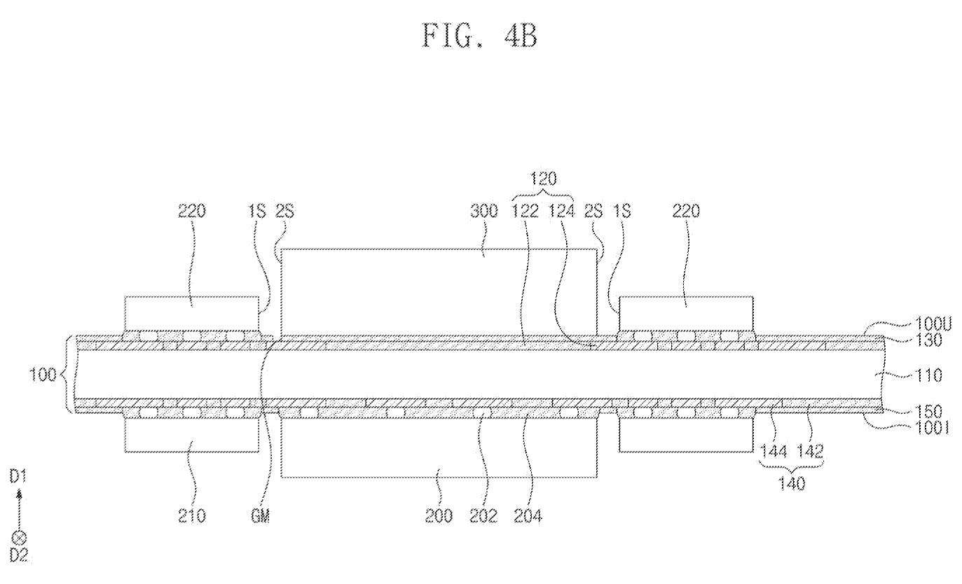

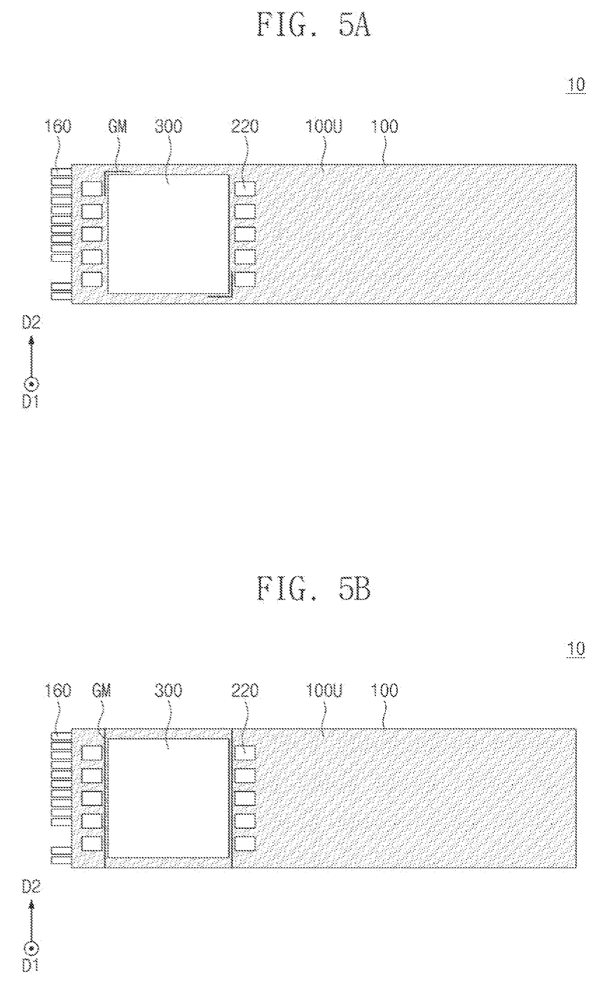

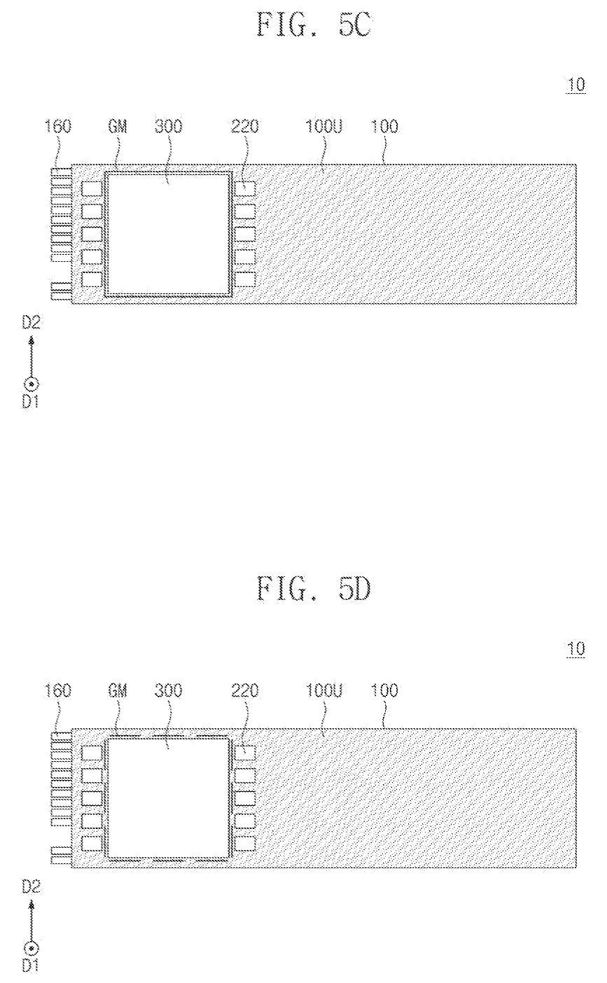

FIGS. 1 and 2 are perspective views for describing a semiconductor package according to one or more embodiments of the present disclosure. FIG. 2 is a perspective view in which a semiconductor package 10 of FIG. 1 is turned over, and then an upper surface 100u of a substrate 100 is seen from an upper side thereof. FIG. 3A is a cross-sectional view, for describing the semiconductor package according to one or more embodiments of the present disclosure, taken along line A-A’ of FIG. 2. FIG. 3B is an enlarged diagram illustrating region P1 of FIG. 3A. FIG. 4A is a plan view for describing the semiconductor package according to one or more embodiments of the present disclosure. FIG. 4B is a cross-sectional view, for describing the semiconductor package according to one or more embodiments of the present disclosure, taken along line B-B’ of FIG. 4A. FIGS. 5A to 5D are plan views for describing the semiconductor package according to one or more embodiments of the present disclosure.

Referring to FIGS. 1 to 3B, the substrate 100 may be provided. The substrate 100 may be a printed circuit board (PCB). The substrate 100 may have a lower surface 100l and an upper surface 100u on opposite sides of the substrate 100. The substrate 100 may include a core layer 110, an upper substrate wire layer 120 and an upper insulating layer 130 sequentially stacked in a first direction D1 vertical to the lower surface 100l of the substrate 100. The core layer 110 may extend in one direction. The core layer 110 may include one core pattern on a plane. According to an embodiment of the present disclosure, while the core layer 110 is described as having one core pattern, the present disclosure is not limited thereto. According to one or more embodiments, the core layer 110 may include two or more core patterns. That is, the substrate 100 may include a plurality of core patterns spaced apart from each other on a plane. The core layer 110 may include an insulating material. For example, the core layer 110 may include any one of glass fiber, a ceramic plate, epoxy and a resin.

The upper substrate wire layer 120 may be formed on an upper surface of the core layer 110. The upper substrate wire layer 120 may include an upper substrate insulating pattern 122 and an upper substrate wire pattern 124. The upper substrate wire pattern 124 may at least partially cover the upper surface of the core layer 110. The upper substrate wire pattern 124 may be formed so as to partially expose the rest of the upper surface of the core layer 110. The upper substrate wire pattern 124 may include a ground wire, a power wire and a signal wire. The upper substrate wire pattern 124 may include a conductive material. For example, the upper substrate wire pattern 124 may include copper. Specifically, the upper substrate wire pattern 124 may include a copper pattern formed of a copper clad laminate.

The upper substrate insulating pattern 122 may partially cover the rest of the upper surface of the exposed core layer 110. The upper substrate insulating pattern 122 may surround the upper substrate wire pattern 124 while allowing an upper surface of the upper substrate wire pattern 124 to remain exposed. The upper substrate insulating pattern 122 may include an insulating material. For example, the upper substrate insulating pattern 122 may include prepreg, an aginomoto buildup film (ABF), FR-4 or bismaleimide triazine (BT). Alternatively, the upper substrate insulating pattern 122 may include an insulating polymer or a photoimageable dielectric (PID). For example, the photoimageable dielectric may include at least one of photoimageable polyimide, polybenzoxazole (PBO), a phenol-based polymer or a benzocyclobutene-based polymer.

The upper insulating layer 130 covering the upper substrate wire layer 120 on the upper surface of the core layer 110 may be provided. The upper insulating layer 130 may at least partially cover an upper surface of the upper substrate wire layer 120. The upper surface of the upper substrate wire pattern 124 may be partially exposed by the upper insulating layer 130. The upper insulating layer 130 may include an insulating material. For example, the upper insulating layer 130 may include prepreg, an aginomoto buildup film (ABF), FR-4 or bismaleimide triazine (BT). A material that constitutes the upper insulating layer 130 may be the same as a material that constitutes the upper substrate insulating pattern 122 of the upper substrate wire layer 120, but the present disclosure is not limited thereto.

A lower substrate wire layer 140 may be formed on a lower surface of the core layer 110. The lower substrate wire layer 140 may include a lower substrate insulating pattern 142 and a lower substrate wire pattern 144. The lower substrate wire pattern 144 may at least partially cover the lower surface of the core layer 110. The lower substrate wire pattern 144 may be formed so as to partially expose the rest of the lower surface of the core layer 110. The lower substrate wire pattern 144 may include a ground wire, a power wire and a signal wire. The lower substrate wire pattern 144 may include a conductive material. For example, the lower substrate wire pattern 144 may include copper. Specifically, the lower substrate wire pattern 144 may include a copper pattern formed of a copper clad laminate.

The lower substrate insulating pattern 142 may partially cover the rest of the lower surface of the exposed core layer 110. The lower substrate insulating pattern 142 may surround the lower substrate wire pattern 144 while allowing a lower surface of the lower substrate wire pattern 144 to remain exposed. The lower substrate insulating pattern 142 may include an insulating material. For example, the lower substrate insulating pattern 142 may include prepreg, an aginomoto buildup film (ABF), FR-4 or bismaleimide triazine (BT). Alternatively, the lower substrate insulating pattern 142 may include an insulating polymer or a photoimageable dielectric (PID). For example, the photoimageable dielectric may include at least one of photoimageable polyimide, polybenzoxazole (PBO), a phenol-based polymer or a benzocyclobutene-based polymer.

A lower insulating layer 150 covering the lower substrate wire layer 140 on the lower surface of the core layer 110 may be provided. The lower insulating layer 150 may at least partially cover a lower surface of the lower substrate wire layer 140. The lower surface of the lower substrate wire pattern 144 may be partially exposed by the lower insulating layer 150. The lower insulating layer 150 may include an insulating material. For example, the lower insulating layer 150 may include prepreg, an aginomoto buildup film (ABF), FR-4 or bismaleimide triazine (BT). A material that constitutes the lower insulating layer 150 may be the same as a material that constitutes the lower substrate insulating pattern 142 of the lower substrate wire layer 140, but the present disclosure is not limited thereto.

The substrate 100 may include a connector 160 disposed on one side of the substrate 100. The connector 160 may include a plurality of pins. In a plan view, the pins may have a shape of a line extending on one side surface of the substrate 100 in a direction parallel to the lower surface 100l of the substrate 100. The connector 160 may serve to physically connect the substrate 100 to an external device. The connector 160 may serve to transfer an electrical signal to an outside of a package. A number and disposition of the plurality of pins in the connector 160 may be changed according to a communication interface between the semiconductor package 10 and the external device.

Vertical connection terminals vertically penetrating the core layer 110 may be included. The vertical connection terminals may extend from the lower surface of the core layer 110 toward the upper surface of the core layer 110. The vertical connection terminals may be exposed onto the lower surface and the upper surface of the core layer 110. The vertical connection terminals may electrically connect the lower substrate wire layer 140 and the upper substrate wire layer 120. One end of the vertical connection terminal may be in contact with the upper substrate wire pattern 124. The other end of the vertical connection terminal may be in contact with the lower substrate wire pattern 144. The vertical connection terminals may include a metal material such as copper (Cu) or tungsten (W).

A memory package 200 may be mounted on the lower surface 100l of the substrate 100. The memory package 200 may include at least one nonvolatile memory device. For example, the memory package 200 may include a NAND flash memory device. The semiconductor package 10 may be a solid state drive (SSD), but the present disclosure is not limited thereto. According to one or more embodiments, the memory device included in the memory package 200 may be a memory device such as a resistive random access memory (ReRAM), a phase-change random access memory (PRAM), or a magnetic random access memory (MRAM). The memory package 200 may have a planar shape of a tetragon, but the present disclosure is not limited thereto.

The memory package 200 may be mounted as a ball grid array (BGA) on the substrate 100. The memory package 200 may be electrically connected to the substrate 100 through first connection terminals 202. The first connection terminals 202 may be provided between the memory package 200 and the lower substrate wire layer 140. The first connection terminals 202 may include a solder ball or a solder bump. The first connection terminals 202 may electrically connect the memory device included in the memory package 200 to the substrate 100. One end of the first connection terminal 202 may be in contact with the lower surface of the exposed lower substrate wire pattern 144. The other end of the first connection terminal 202 may be in contact with the memory package 200. An underfill layer 204 may be provided between the lower substrate wire layer 140 and the memory package 200. The underfill layer 204 may fill a space between the substrate 100 and the memory package 200, and may surround the first connection terminals 202.

A plurality of first devices 210 may be mounted on the lower surface 100l of the substrate 100. The first devices 210 may be disposed horizontally spaced apart from the memory package 200 on the lower surface 100l of the substrate 100. The first devices 210 may be arranged along one side surface of the memory package 200. For example, the first devices 210 may be disposed in at least one column extending in a second direction D2 parallel to the one side surface of the memory package 200. The first devices 210 may be arranged in two columns extending in the second direction D2. A number and disposition of the first devices 210 may be changed as needed. The first devices 210 may be excluded as needed. However, for convenience of description, hereinafter, the present disclosure will be described assuming that the semiconductor package 10 includes the first devices 210 disposed in two columns extending along the second direction D2. The first devices 210 may be disposed spaced apart from each other in the two columns in the second direction D2. The memory package 200 may be disposed between the two columns of the first devices 210. Put another way, the first devices 210 may be disposed in columns along opposite side surfaces of the memory package 200. The first devices 210 may include a passive device such as a capacitor, but the present disclosure is not limited thereto. For example, the first devices 210 may include driving circuits for driving the memory package 200.

The upper surface 100u of the substrate 100 may include a memory region 200P. In the present specification, the memory region 200P may mean a region in which the memory package 200 is provided on the lower surface 100l of the substrate 100 is vertically projected onto the upper surface 100u of the substrate 100 (i.e., a region of the upper surface 100u opposite the region where the memory package 200 is provided on the lower surface 100l). In the present disclosure, the memory region 200P may not be visually seen on the upper surface 100u of the substrate 100 as a region defined for convenience of description. A planar shape and a planar area of the memory region 200P may be the same as a planar shape and a planar area of the memory package 200.

Second devices 220 may be disposed on the upper surface 100u of the substrate 100. The second devices 220 may be disposed horizontally spaced apart from each other on the upper surface 100u of the substrate 100. The second devices 220 may be disposed in at least one column extending in the second direction D2 on the upper surface 100u of the substrate 100. For example, the second devices 220 may be disposed in two columns extending in the second direction D2. A number and disposition of the second devices 220 may be changed as needed. However, for convenience of description, hereinafter, the present disclosure assumes that the semiconductor package 10 includes the second devices 220 arranged in the two columns. The two columns of the second devices 220 may be horizontally spaced apart from each other. The second devices 220 may be disposed along opposite side surfaces of the memory region 200P. Put another way, the memory region 200P may be disposed between the two columns of the second devices 220. The second devices 220 may have a first side surface 1S. The first side surface 1S of the second devices 220 may mean a side surface, parallel to the second direction D2 and nearest to the memory region 200P on a plan view, among the side surfaces of the second devices 220. Put another way, the first side surface 1S of the second devices 220 of any one column, and the first side surface 1S of the second devices 220 of the other column, of the two columns of the second devices 220, face the memory region 200P and thus may face each other. The second devices 220 may include a passive device. For example, each of the second devices 220 may include a capacitor. Each of the second devices 220 may include a first electrode, a second electrode and a capacitor dielectric layer interposed between the first electrode and the second electrode. For example, each of the second devices 220 may be a multi-layered ceramic capacitor (MLCC), but the present disclosure is not limited thereto. The second devices 220 may vertically overlap the first devices 210. The first devices 210 and the second devices 220 may be aligned with each other in the first direction D1.

A guide mark GM may be disposed on the upper surface 100u of the substrate 100. The guide mark GM may have a shape of a trench recessed from the upper surface 100u of the substrate 100 toward an inside of the substrate 100. The guide mark GM may be recessed from the upper surface of the upper insulating layer 130 toward an inside of the upper insulating layer 130. A height of the guide mark GM measured from a bottom surface of the guide mark GM in the first direction D1 may be about 33% to about 100% of a height of the upper insulating layer 130 measured in the first direction D1. In an embodiment, the guide mark GM of the upper insulating layer 130 may completely penetrate the upper insulating layer 130. The upper surface of the upper substrate wire layer 120 may be exposed onto the guide mark GM. The bottom surface of the guide mark GM may be coplanar with the upper surface of the upper substrate wire layer 120. More specifically, the upper substrate wire pattern 124 may be provided on the bottom surface of the guide mark GM. Accordingly, the upper surface of the upper substrate wire pattern 124 of the upper substrate wire layer 120 may be partially exposed onto the guide mark GM.

The guide mark GM may be disposed spaced apart from the second devices 220. The guide mark GM may be disposed between the two columns of the second devices 220. The guide mark GM may be provided between the memory region 200P and the second devices 220. The guide mark GM may be disposed on the first side surface 1S of the second devices 220 of the any one column of the second devices 220. The guide mark GM may be about 2 mm to about 10 mm spaced apart from the first side surface 1S of the second devices 220 of the any one column, but the present disclosure is not limited thereto. In a plan view, the guide mark GM may extend along a border of the memory region 200P. On a plan view, the guide mark GM may at least partially surround the border (or perimeter) of the memory region 200P. A position at which the memory package 200 is disposed on the lower surface 100l of the substrate 100 may be confirmed through the guide mark GM even on the upper surface 100u of the substrate 100. The guide mark GM may partition a region in which the memory region 200P and the second devices 220 are disposed. The guide mark GM may partition or define a region in which a heat transfer layer (to be described later) is provided. The guide mark GM may be provided in plurality as needed (see, e.g., FIG. 4A).

Referring to FIGS. 4A and 4B, the semiconductor package 10 may further include a heat transfer layer 300 provided on the upper surface 100u of the substrate 100. The heat transfer layer 300 may be disposed inside the region defined by the guide mark GM. Since the guide mark GM extends along the border of the memory region 200P, the region defined by the guide mark GM may be substantially the same as the memory region 200P. The heat transfer layer 300 may vertically overlap the memory package 200. The heat transfer layer 300 may have the same planar area as the memory package 200. The heat transfer layer 300 may have a planar shape of a tetragon, but the present disclosure is not limited thereto, and the planar area and the planar shape of the heat transfer layer 300 may be different from the planar area and the planar shape of the memory package 200. Hereinafter, description will be made on the basis of an embodiment of FIG. 4A.

The heat transfer layer 300 may be horizontally spaced apart from the second devices 220 on the upper surface 100u of the substrate 100. Put another way, the second devices 220 may be horizontally spaced apart from the region defined by the guide mark GM. The heat transfer layer 300 may be disposed between the two columns of the second devices 220. A height in the first direction D1 of the heat transfer layer 300 may be greater than heights in the first direction D1 of the second devices 220. An upper surface of the heat transfer layer 300 may be located at a higher level than upper surfaces of the second devices 220.

The heat transfer layer 300 may be formed of a material having a high thermal conductivity so as to dissipate heat. For example, the heat transfer layer 300 may include a thermal interface material (TIM). The TIM may be formed of a material having a high thermal conductivity, that is, a low thermal resistivity, for example, grease, a tape, an elastomer filling pad, a phase transition material, and the like. However, a material of the TIM is not limited to the above materials.

The guide mark GM may be disposed between a region in which the heat transfer layer 300 is provided and a region in which the second devices 220 are provided. The guide mark GM may at least partially surround a border of the heat transfer layer 300. For example, the heat transfer layer 300 may include two second side surfaces 2S parallel to the second direction D2. In this case, the second side surfaces 2S of the heat transfer layer 300 may respectively mean side surfaces nearest to the two columns of the second devices 220. The guide mark GM may be disposed between the second side surface 2S of the heat transfer layer 300 and the first side surface 1S of the second devices 220. The guide mark GM may align a region in which the heat transfer layer 300 is provided and a region in which the memory package 200 is provided in the first direction D1. An area occupied on the upper surface 100u of the substrate 100 by the heat transfer layer 300 may be the same as an area occupied on the lower surface 100l of the substrate 100 by the memory package 200. Put another way, the heat transfer layer 300 may have the same planar area as the memory package 200.

The heat transfer layer 300 and the memory package 200 may be aligned with each other in the first direction D1. Accordingly, the heat transfer layer 300 may provide a heat path through which heat generated by the memory package 200 is dissipated. A memory device included in the memory package 200 may be a main heat source that generates heat inside the semiconductor package 10. The heat generated by the memory package 200 may be efficiently dissipated outside the semiconductor package 10 through the heat transfer layer 300.

In addition, the guide mark GM may horizontally space the heat transfer layer 300 apart from the second devices 220 adjacent thereto. Accordingly, the heat transfer layer 300 may be prevented from electrically affecting the second devices 220. Accordingly, a semiconductor package with improved electrical stability may be provided.

It is illustrated in FIGS. 1 to 4B that the guide mark GM is spaced apart from a boundary of the memory region 200P and is disposed outside the memory region 200P, but the present disclosure is not limited thereto. For example, the guide mark GM may vertically overlap the boundary of the memory region 200P.

Alternatively, the guide mark GM may be provided inside the memory region 200P. Put another way, a size of the region partitioned by the guide mark GM may be smaller than a size of the memory region 200P. Accordingly, a region in which the heat transfer layer 300 is provided and a region in which the memory package 200 is provided may not have the same size as each other. For example, as needed, the heat transfer layer 300 may have a smaller planar area than the memory package 200. Hereinafter, description will be made on the basis of the embodiments of FIGS. 1 to 4B.

Hereinafter, a planar shape and disposition of the guide mark GM according to one or more embodiments of the present disclosure will be described in more detail with reference to FIGS. 5A to 5D.

Referring to FIG. 5A, the guide mark GM may have a planar shape of the letter “L” (e.g., the guide mark GM may form a right angle or otherwise form a “corner” shape). The heat transfer layer 300 may include two edges facing each other. In a plan view, the guide mark GM may surround at least one of the two edges of the heat transfer layer 300. For example, two guide marks GM may be provided on the upper surface 100u of the substrate 100. In a plan view, each of the guide marks GM may surround any one of the two edges of the heat transfer layer 300.

Referring to FIG. 5B, the guide mark GM may have a planar shape of a line extending in the second direction D2. A length of the guide mark GM may be the same as or smaller than a length in the second direction D2 of the substrate 100. The length of the guide mark GM may be the same as or longer than a length in the second direction D2 of any one among the second devices 220. In a plan view, the guide mark GM may be disposed outside the second side surfaces 2S of the heat transfer layer 300. The guide mark GM may be disposed between the second devices 220 of any one column of the two columns of the second devices 220 and the heat transfer layer 300. Specifically, in a plan view, the guide mark GM may be disposed between any one of the second side surfaces 2S of the heat transfer layer 300 and the first side surface 1S of the second devices 220 of any one column adjacent to the second side surface 2S. For example, two guide marks GM may be provided on the upper surface 100u of the substrate 100. in a plan view, each of the guide marks GM may be provided outside each of the second side surfaces 2S of the heat transfer layer 300.

Referring to FIG. 5C, the guide mark GM may extend along the border of the heat transfer layer 300. The guide mark GM may have a planar shape of a closed ring. More specifically, the guide mark GM may have the planar shape of a tetragonal ring (e.g., a square or rectangle). The guide mark GM may surround the heat transfer layer 300.

Referring to FIG. 5D, the substrate 100 may include a plurality of guide marks GM arranged along the border of the heat transfer layer 300. In a plan view, the guide marks GM may be disposed spaced apart from each other at a constant interval along the border (or perimeter) of the heat transfer layer 300.

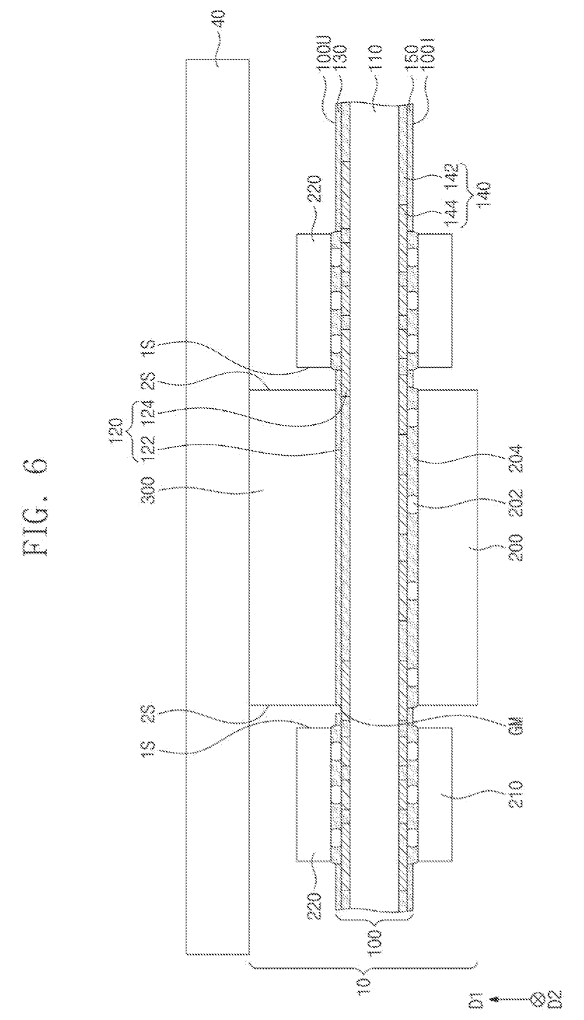

FIG. 6 is a cross-sectional view for describing the semiconductor package according to one or more embodiments of the present disclosure.

Referring to FIG. 6, a heat dissipation body 400 may be provided on the semiconductor package 10. The heat dissipation body 400 may be disposed on the upper surface 100u of the substrate 100. A lower surface of the heat dissipation body 400 may be in contact with the upper surface of the heat transfer layer 300. The semiconductor package 10 may be attached onto the lower surface of the heat dissipation body 400 through the heat transfer layer 300.

The heat dissipation body 400 may include a metal material, a ceramic material, a carbon material or a polymer material that has a high thermal conductivity. The heat dissipation body 400 may have a shape of an uneven structure as needed.

The heat dissipation body 400 may dissipate heat generated by the semiconductor package 10 outside. Heat generated by the memory package 200 and the first and second devices 210 and 220 may be transferred along the heat transfer layer 300 to the heat dissipation body 400. The heat may be dissipated away from the semiconductor package 10 through the heat dissipation body 400. That is, the heat generated by the semiconductor package 10 may be rapidly dissipated, and a semiconductor package with improved heat dissipation characteristics may be provided.

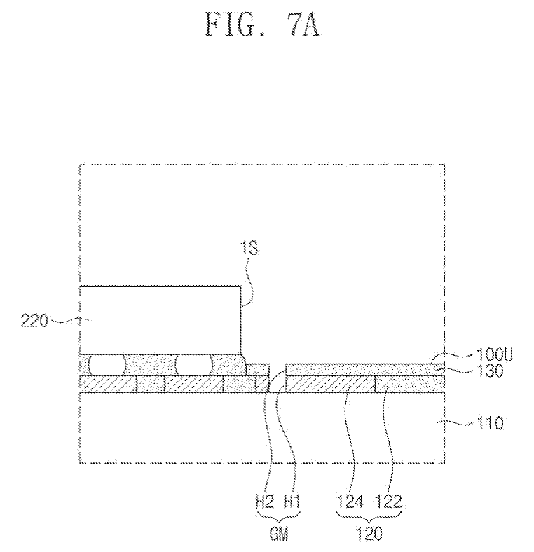

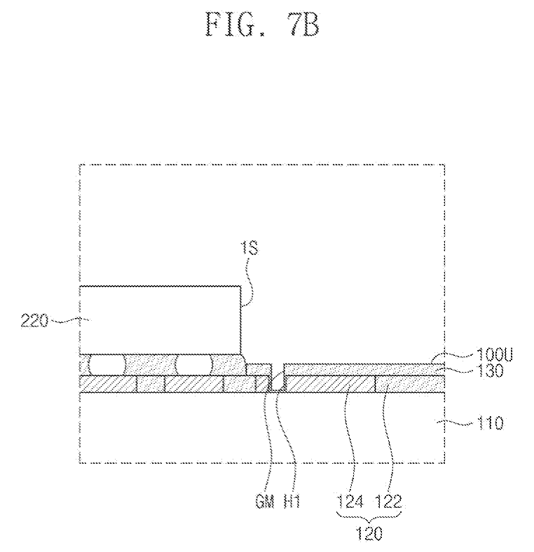

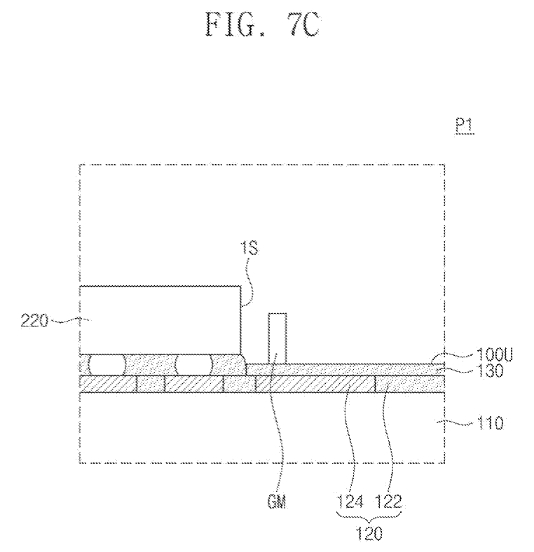

FIGS. 7A to 7C are cross-sectional views for describing the semiconductor package according to one or more embodiments of the present disclosure. Similarly to FIG. 3B, only a part of the semiconductor package is enlarged and illustrated in FIGS. 7A to 7C. Hereinafter, a structure and a shape of the guide mark GM according to one or more embodiments of the present disclosure will be described in more detail with reference to FIGS. 7A to 7C.

It is described in FIGS. 3A and 3B that the height in the first direction D1 of the guide mark GM may be the same as the height in the first direction D1 of the upper insulating layer 130, but the present disclosure is not limited thereto. Referring to FIG. 7A, the height of the guide mark GM may be greater than the height of the upper insulating layer 130. The bottom surface of the guide mark GM may be located at a level lower than a lower surface of the upper insulating layer 130. The guide mark GM may at least partially penetrate the upper substrate wire layer 120 in the first direction D1. In an embodiment, the guide mark GM may completely penetrate the upper substrate wire layer 120 and the upper insulating layer 130. The upper surface of the core layer 110 may be exposed onto the guide mark GM. The bottom surface of the guide mark GM may be coplanar with the upper surface of the core layer 110.

Put another way, the upper substrate wire layer 120 may include a first hole H1 penetrating the upper substrate wire layer 120. The upper insulating layer 130 may include a second hole H2 penetrating the upper insulating layer 130. A region in which the second hole H2 is formed may vertically overlap a region in which the first hole H1 is formed. A planar shape and disposition of the second hole H2 may be the same as a planar shape and disposition of the first hole H1. Inner side surfaces of the first hole H1 may be vertically aligned with inner side surfaces of the second hole H2. The upper insulating layer 130 may cover the upper surface of the upper substrate wire layer 120 except for the first hole H1. The first hole H1 and the second hole H2 may form one groove recessed from the upper surface 100u of the substrate 100 toward an inside of the substrate 100. The one groove may simultaneously penetrate the upper substrate wire layer 120 and the upper insulating layer 130. The one groove may mean the guide mark GM.

It is illustrated in FIG. 7A that the upper surface of the core layer 110 is exposed onto the bottom surface of the guide mark GM, but the present disclosure is not limited thereto. Referring to FIG. 7B, as in FIG. 7A, the substrate 100 may include the first hole H1 penetrating the upper substrate wire layer 120. However, unlike FIG. 7A, the upper insulating layer 130 may cover the upper surface of the upper substrate wire layer 120, and the inner side surfaces and a bottom surface of the first hole H1. Since the upper insulating layer 130 covers the entire upper surface of the upper substrate wire layer 120 including the first hole H1, the upper insulating layer 130 may have a step in a region in which the first hole H1 is formed. In this case, the step may mean the guide mark GM. The upper surface of the core layer 110 may not be exposed onto the bottom surface of the guide mark GM.

It is described in FIGS. 3A, 3B, 7A and 7B that the guide mark GM has a shape of a trench recessed from the upper surface 100u of the substrate 100 toward an inside of the substrate 100, but the present disclosure is not limited thereto. Referring to FIG. 7C, the guide mark GM may be provided on the upper surface 100u of the substrate 100. The guide mark GM may protrude onto the upper surface 100u of the substrate 100. The height in the first direction D1 of the guide mark GM may be the same as or smaller than the height in the first direction D1 of the heat transfer layer 300 (see FIG. 4B). For example, the height in the first direction D1 of the guide mark GM may be about 0.6 mm to about 3 mm, but the present disclosure is not limited thereto. A planar shape and disposition of the guide mark GM may be substantially the same as what is described with reference to FIGS. 5A to 5D. A material that constitutes the guide mark GM may be different from a material that constitutes the upper insulating layer 130.

Since the guide mark GM protrudes onto the upper surface 100u of the substrate 100, the guide mark GM may prevent the heat transfer layer 300 from flowing outside a region partitioned by the guide mark GM. Put another way, the guide mark GM may space the heat transfer layer 300 apart from the second devices 220. Accordingly, the semiconductor package with more improved electrical stability may be provided.

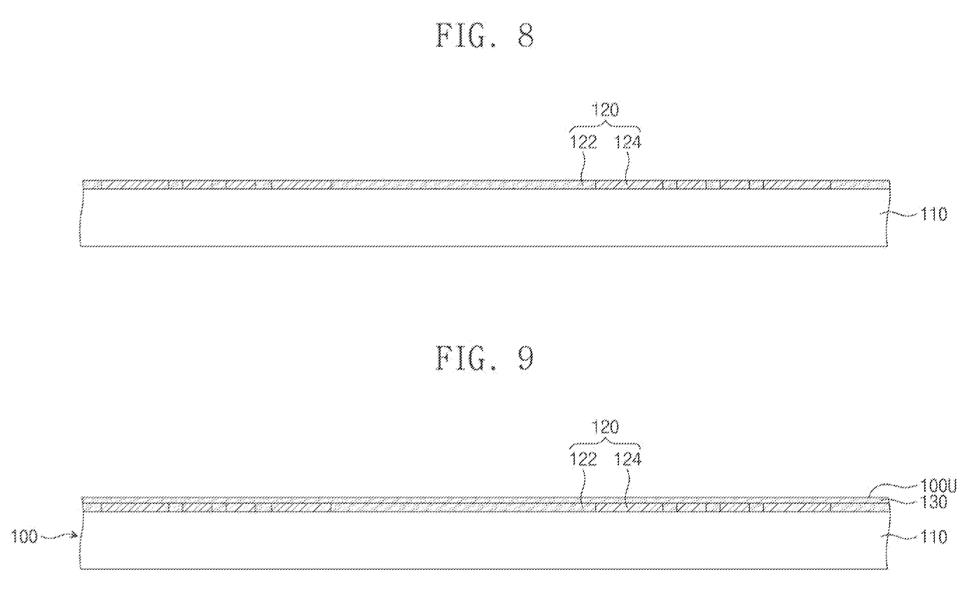

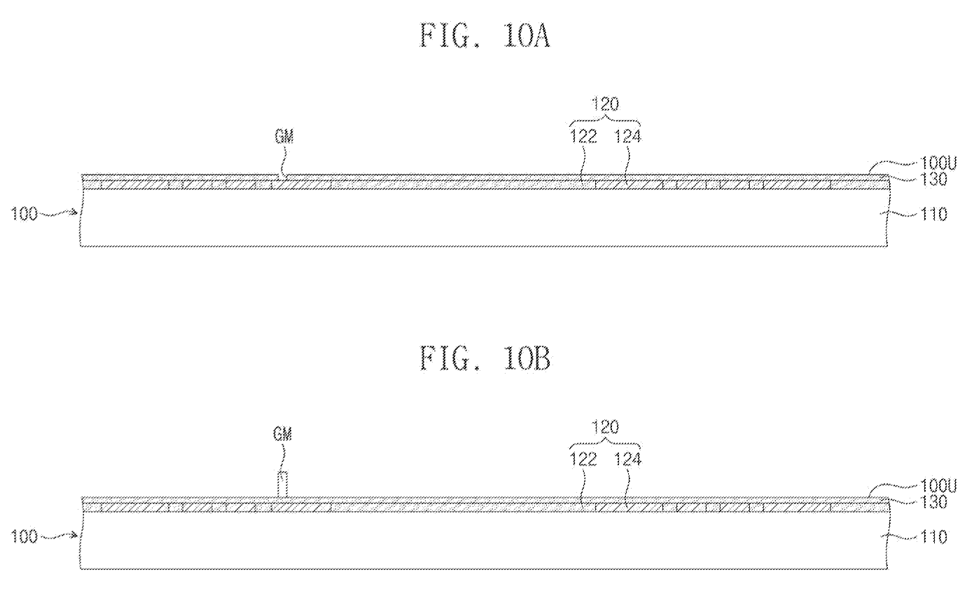

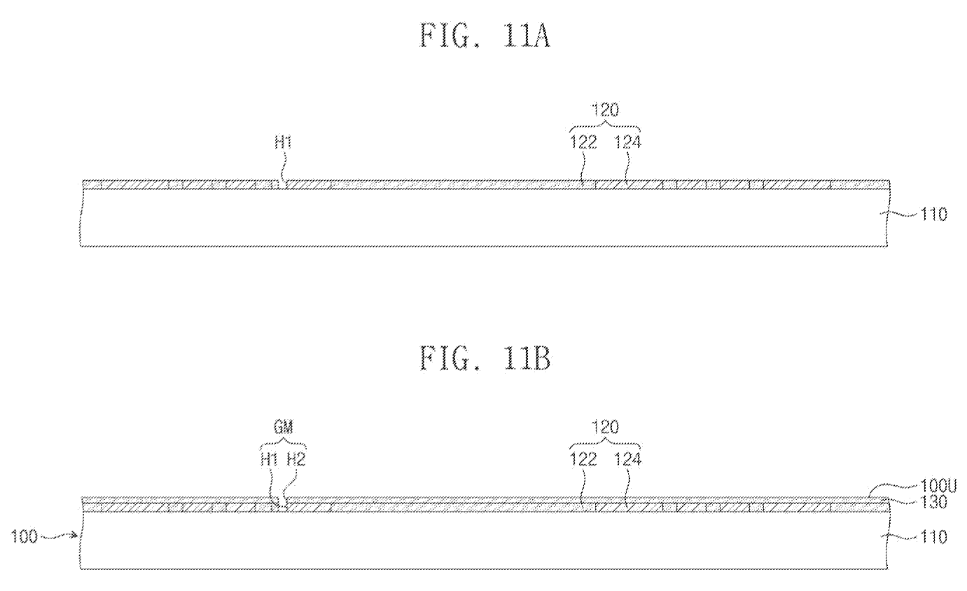

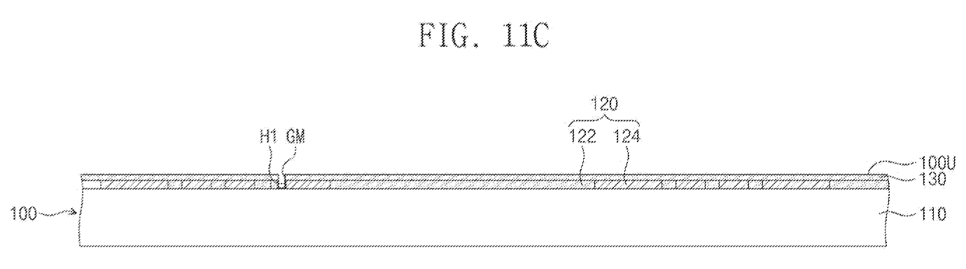

FIGS. 8 to 11C are cross-sectional views for describing a method of manufacturing the substrate 100 of the semiconductor package according to one or more embodiments of the present disclosure. For convenience of description, FIGS. 8 to 11C illustrate only some components of the semiconductor package. FIG. 10A is a cross-sectional view illustrating a process of manufacturing the semiconductor package having a cross-section of FIG. 3A. FIG. 10B is a cross-sectional view illustrating a process of manufacturing the semiconductor package having a cross-section of FIG. 7C. FIG. 11B is a cross-sectional view illustrating a process of manufacturing the semiconductor package having a cross-section of FIG. 7A. FIG. 11C is a cross-sectional view illustrating a process of manufacturing the semiconductor package having a cross-section of FIG. 7B.

Referring to FIG. 8, the upper substrate wire layer 120 may be formed on the upper surface of the core layer 110. For example, the upper substrate wire layer 120 may be manufactured by forming the upper substrate insulating pattern 122 and the upper substrate wire pattern 124 on the upper surface of the core layer 110. More specifically, the upper substrate insulating pattern 122 may be formed by forming an insulating layer on the upper surface of the core layer 110, and then patterning the insulating layer. The upper substrate wire pattern 124 may be formed by forming a conductive layer on the insulating layer, and then patterning the conductive layer. In this case, the upper substrate wire pattern 124 may be partially exposed onto the upper substrate insulating pattern 122.

Referring to FIG. 9, the upper insulating layer 130 may be formed on the upper substrate wire layer 120. The upper insulating layer 130 may include a gel-soft polymer such as a solder resist material. A material forming the upper insulating layer 130 may be applied on the upper surface of the upper substrate wire layer 120 to cover the entire upper surface of the upper substrate wire layer 120.

Referring to FIG. 10A, the guide mark GM may be formed by patterning the upper insulating layer 130. The guide mark GM may penetrate the upper insulating layer 130. The upper surface of the upper substrate wire layer 120 may be partially exposed onto the guide mark GM. The bottom surface of the guide mark GM may be coplanar with the upper surface of the upper substrate wire layer 120. In this case, the process of patterning the upper insulating layer 130 may mean a process of forming a pattern for electrical connection on the substrate 100. More specifically describing, a pattern for electrical connection with the second devices 220 may be simultaneously formed on the guide mark GM and the substrate 100 through the patterning process. The upper surface of the upper substrate wire pattern 124 may be partially exposed onto the upper insulating layer 130 through the pattern. The exposed upper substrate wire pattern 124 may electrically connect the substrate 100 and the second devices 220 mounted later. Since the guide mark GM is formed in the patterning process, an additional manufacturing process for forming the guide mark GM may not be needed. As described above, the substrate 100 of FIG. 3A may be formed.

Referring to FIG. 10B, the guide mark GM may be formed on a result of FIG. 9. The guide mark GM may be printed on the upper insulating layer 130 through a silk screen process. The guide mark GM may protrude onto the upper surface 100u of the substrate 100. As described above, the substrate 100 of FIG. 7C may be formed.

Referring to FIG. 11A, the upper substrate wire layer 120 may be formed on the upper surface of the core layer 110. However, unlike FIG. 8, the first hole H1 may be formed on the upper substrate wire layer 120. More specifically, the upper substrate insulating pattern 122 may be formed by forming an insulating layer on the upper surface of the core layer 110 and then patterning the insulating layer. The upper substrate wire pattern 124 may be formed by forming a conductive layer on the insulating layer, and then patterning the conductive layer. The first hole H1 may be formed in the upper substrate wire pattern 124 in a process of patterning the conductive layer.

Referring to FIG. 11B, the upper insulating layer 130 may be formed on a result of FIG. 11A. The upper insulating layer 130 may include a gel-soft polymer such as a solder resist material. A material forming the upper insulating layer 130 may be applied on the upper surface of the upper substrate wire layer 120 to cover the upper surface of the upper substrate wire layer 120. The upper insulating layer 130 may not cover the inner side surfaces and the bottom surface of the first hole H1. The upper surface of the core layer 110 may be exposed outside through the first hole H1. Put another way, the upper insulating layer 130 may have the second hole H2 penetrating the upper insulating layer 130 on a region in which the first hole H1 is formed. The second hole H2 may have the same planar shape and disposition as the first hole H1. The inner side surfaces of the first hole H1 may be vertically aligned with the inner side surfaces of the second hole H2. The first hole H1 and the second hole H2 may form one groove simultaneously penetrating the upper substrate wire layer 120 and the upper insulating layer 130. The one groove may constitute the guide mark GM. As described above, the substrate 100 of FIG. 7A may be formed.

Referring to FIG. 11C, the upper insulating layer 130 may be formed on a result of FIG. 11A. In this case, unlike FIG. 11B, the upper insulating layer 130 may cover the inner side surfaces and the bottom surface of the first hole H1. The core layer 110 and the upper substrate wire layer 120 may not be exposed onto the first hole H1. Since the entire upper surface of the upper substrate wire layer 120 including the first hole H1 is covered, the upper insulating layer 130 may have a step in a region in which the first hole H1 is formed. In this case, the step may mean the guide mark GM. As described above, the substrate 100 of FIG. 7B may be formed.

Referring back to FIGS. 1, 2 and 4, the memory package 200, the heat transfer layer 300, the first devices 210 and the second devices 220 may be mounted on the substrate 100 manufactured in the manufacturing methods. The memory package 200 and the first devices 210 may be mounted on the lower surface 100l of the substrate 100. The heat transfer layer 300 may be mounted on the upper surface 100u of the substrate 100. In this case, the heat transfer layer 300 may vertically overlap the memory package 200. A region in which the heat transfer layer 300 is provided may at least partially overlap the memory region 200P. The second devices 220 horizontally spaced apart from the heat transfer layer 300 may be mounted on the upper surface 100u of the substrate 100. The guide mark GM may be disposed between a region in which the heat transfer layer 300 is provided and a region in which the second devices 220 are provided. The guide mark GM may define a region in which the heat transfer layer 300 is provided on the substrate 100 on the upper surface 100u of the substrate 100. The guide mark GM may at least partially surround the border of the heat transfer layer 300. As described above, the semiconductor package including the guide mark GM having various planar shapes may be manufactured.

A semiconductor package according to one or more embodiments of the present disclosure may partition a region in which a heat transfer layer is provided by using a guide mark. The guide mark may dispose the heat transfer layer on a memory package. Accordingly, heat generated by the memory package may be efficiently dissipated. Accordingly, the semiconductor package with improved thermal characteristics may be provided.

In addition, the semiconductor package according to one or more embodiments of the present disclosure may form the guide mark surrounding a circumference of the heat transfer layer to prevent the heat transfer layer from electrically affecting adjacent devices. Accordingly, the semiconductor package with improved electrical stability may be provided.

Although the one or more embodiments of the present disclosure have been described, it is understood that the present disclosure should not be limited to these embodiments but various changes and modifications can be made by one ordinary skilled in the art within the spirit and scope of the present disclosure as hereinafter claimed. Therefore, it should be understood that the embodiments described above are exemplary in all respects and are not intended to be limiting.

What is claimed is:

1. A semiconductor package comprising:
a substrate comprising an upper surface and a lower surface on opposite sides of the substrate;
a memory package on the lower surface of the substrate;
a guide mark on the upper surface of the substrate, wherein the guide mark is recessed from the upper surface of the substrate toward an inside of the substrate;
a heat transfer layer on the upper surface of the substrate, wherein the heat transfer layer vertically overlaps with the memory package; and
a device horizontally spaced apart from the heat transfer layer on the upper surface of the substrate,
wherein the guide mark is between a region in which the heat transfer layer is provided and a region in which the device is provided.

2. The semiconductor package of claim 1, further comprising a plurality of devices comprising the device,
wherein the plurality of devices are arranged along a first direction parallel to the upper surface of the substrate, and
wherein the first direction is parallel to a side surface of the heat transfer layer.

3. The semiconductor package of claim 2, wherein the guide mark comprises a line extending along the first direction, and
wherein the guide mark is between the side surface of the heat transfer layer and the plurality of devices.

4. The semiconductor package of claim 1, wherein the heat transfer layer comprises a tetragon,
wherein the heat transfer layer comprises two edges facing each other,
wherein the guide mark comprises a plurality of guide marks, and
wherein each of the plurality of guide marks surrounds any one of the two edges of the heat transfer layer.

5. The semiconductor package of claim 1, wherein the guide mark extends along at least a portion of a border of the heat transfer layer, and
wherein the guide mark comprises a tetragonal ring.

6. The semiconductor package of claim 1, wherein the device comprises a capacitor, and
wherein the capacitor comprises a first electrode, a second electrode and a capacitor dielectric layer between the first electrode and the second electrode.

7. The semiconductor package of claim 1, further comprising a heat dissipation body on the upper surface of the substrate,
wherein the heat transfer layer has a height greater than a height of the device, and
wherein the heat dissipation body is in contact with an upper surface of the heat transfer layer.

8. The semiconductor package of claim 1, wherein the substrate further comprises:
a core layer;
an upper substrate wire layer on an upper surface of the core layer; and
an upper insulating layer on an upper surface of the upper substrate wire layer,
wherein the guide mark penetrates the upper insulating layer, and
wherein the upper surface of the upper substrate wire layer is at least partially exposed onto the guide mark.

9. The semiconductor package of claim 1, wherein the substrate further comprises:
a core layer;
an upper substrate wire layer on an upper surface of the core layer; and
an upper insulating layer on an upper surface of the upper substrate wire layer,
wherein the guide mark penetrates the upper substrate wire layer and the upper insulating layer, and
wherein the upper surface of the core layer is at least partially exposed onto the guide mark.

10. A semiconductor package comprising:
a substrate;
a memory package on a lower surface of the substrate; and
a heat transfer layer on an upper surface of the substrate, wherein the heat transfer layer vertically overlaps with the memory package,
wherein the substrate comprises:
a core layer;
an upper substrate wire layer on an upper surface of the core layer; and
an upper insulating layer on an upper surface of the upper substrate wire layer,
wherein the upper substrate wire layer comprises at least one first hole recessed from the upper surface of the upper substrate wire layer toward an inside of the upper substrate wire layer, and
wherein the at least one first hole extends along at least a portion of a border of the heat transfer layer.

11. The semiconductor package of claim 10, wherein the at least one first hole defines a region in which the heat transfer layer is provided on the substrate, and
wherein the semiconductor package further comprises a plurality of devices on the upper surface of the substrate, wherein the plurality of devices are horizontally spaced apart from the region defined by the at least one first hole.

12. The semiconductor package of claim 10, wherein the heat transfer layer comprises a tetragon,
wherein the heat transfer layer comprises two edges facing each other,
wherein the at least one first hole comprises a plurality of first holes, and
wherein each of the plurality of first holes surrounds any one of the two edges of the heat transfer layer.

13. The semiconductor package of claim 10, wherein the at least one first hole comprises a tetragonal ring, and
wherein the at least one first hole surrounds a perimeter of the heat transfer layer.

14. The semiconductor package of claim 10, wherein the at least one first hole penetrates the upper substrate wire layer,
wherein the upper insulating layer covers the upper surface of the upper substrate wire layer except for the at least one first hole, and
wherein the upper surface of the core layer is partially exposed onto the at least one first hole.

15. The semiconductor package of claim 10, wherein the upper insulating layer covers the upper surface of the upper substrate wire layer, an inner side surface of the at least one first hole and a bottom surface of the at least one first hole.

16. A semiconductor package comprising:
a substrate comprising a guide mark protruding from an upper surface of the substrate;
a memory package on a lower surface of the substrate; and
a heat transfer layer on the upper surface of the substrate,
wherein the heat transfer layer vertically overlaps with the memory package, and
wherein the guide mark at least partially surrounds a border of the heat transfer layer.

17. The semiconductor package of claim 16, further comprising devices disposed in two columns extending along a first direction parallel to the upper surface of the substrate,
wherein the heat transfer layer is between the two columns,
wherein the guide mark comprises a line extending in the first direction, and
wherein the guide mark is between the devices of one of the two columns and the heat transfer layer.

18. The semiconductor package of claim 16, wherein the heat transfer layer comprises a tetragon,
wherein the heat transfer layer comprises two edges facing each other,
wherein the guide mark is provided in plurality, and
wherein each of the plurality of guide marks surrounds any one of the two edges of the heat transfer layer.

19. The semiconductor package of claim 16, wherein the guide mark defines a region in which the heat transfer layer is provided on the substrate,
wherein the semiconductor package further comprises:
a device on the upper surface of the substrate, wherein the device is horizontally spaced apart from the region defined by the guide mark; and
a heat dissipation body on the upper surface of the substrate,
wherein the heat transfer layer has a height greater than a height of the device and a height of the guide mark, and
wherein the heat dissipation body is in contact with an upper surface of the heat transfer layer.

20. The semiconductor package of claim 16, wherein the substrate further comprises:
a core layer;
an upper substrate wire layer on an upper surface of the core layer; and
an upper insulating layer on an upper surface of the upper substrate wire layer, and
wherein a material that constitutes the guide mark is different from a material that constitutes the upper insulating layer.
